(19) United States
(12) Patent Application Publication
(10) Pub. No.: US 2012/0003838 A1
(43) Pub. Date: Jan. 5, 2012

(54) PLASMA ETCHING METHOD

(75) Inventors: Kazumasa Ookuma, Kudamatsu (JP); Akito Kouchi, Kudamatsu (JP); Kenichi Kuwahara, Hikari (JP); Michikazu Morimoto, Kudamatsu (JP); Go Saito, Hikari (JP)

(73) Assignee: Hitachi High-Technologies Corporation

(21) Appl. No.: 12/855,265

(22) Filed: Aug. 12, 2010

(30) Foreign Application Priority Data
Jul. 1, 2010 (JP) 2010-150710

(51) Int. Cl. H01L 21/308; H01L 21/3065

(52) U.S. Cl. 438/717; 257/E21.218; 257/E21.232

(57) ABSTRACT

Line-wiggling and striation caused by collapse of a pattern after a silicon dioxide film is etched by plasma with the use of a multilayer resist mask are prevented or suppressed. In a plasma etching method of etching a film to be etched by plasma with the use of a multilayer resist mask, the multilayer resist mask includes an upper layer resist, an inorganic intermediate film, and a lower layer resist, and the method includes a side wall protective film forming step of forming a side wall protective film on a side wall of the lower layer resist.

### CLAIM OF PRIORITY

The present application claims priority from Japanese patent application JP 2010-150710 filed on Jul. 1, 2010, the content of which is hereby incorporated by reference into this application.

### BACKGROUND OF THE INVENTION

1. Field of the Invention

The present invention relates to a plasma etching method for etching a substrate to be treated by using plasma, and more particularly to a plasma etching method using a multilayer resist mask for the purpose of microfabrication.

2. Description of the Related Art

In recent years, the miniaturization of semiconductor integrated circuits has being growing, and plasma etching using a multilayer resist mask has become mainstream. The multilayer resist mask is normally of a three-layer structure having an upper layer resist film, an inorganic intermediate film, and a lower layer resist film, or a two-layer structure having the upper layer resist film and the lower layer resist film. For that reason, as compared with a single-layer ArF resist mask, a working process using dry etching becomes complicated, and a high-level working technique is required.

Also, the more miniaturization of the semiconductor integrated circuits by the multilayer resist mask has been demanded, and a miniaturizing method that applies a slimming technique to the upper layer resist film of the multilayer resist mask, and a miniaturizing method that applies the slimming technique is applied to the intermediate film have been employed.

When the semiconductor integrated circuits are further miniaturized by the slimming technique using the multilayer resist mask, pattern damage or deformation generated in the upper layer resist film or the lower layer resist film is transferred to a film to be etched shown in FIG. 4A-FIG. 4C, and a working pattern configuration is damaged or deformed. The damage and deformation are called “line-wiggling” or “striation”.

In order to prevent the line-wiggling or the striation, Japanese Patent Application Laid-open Publication No. 2004-80033 discloses a technique in which, after production of the resist pattern, a silicon dioxide film is thinly formed on the resist pattern, and then worked. However, in this related art, the number of processes increases, and the difficulty of working becomes high.

### SUMMARY OF THE INVENTION

Also, as the working dimension of the upper layer resist film or the inorganic intermediate film is made thinner, the aspect ratio (a ratio of the vertical dimension to the horizontal dimension) after the lower layer resist film which is an organic film disposed immediately below the inorganic intermediate film has been etched increases more. Then, while the lower layer resist film is being etched, or while the film to be etched is being etched with the lower layer resist film as a mask, pattern damage such as pattern collapse is generated. When the pattern is damaged, the damage is transferred to the film to be etched, and the line-wiggling or the striation in which the working pattern configuration is damaged is generated. As mechanisms that generate the pattern collapse which induces the line-wiggling or the striation, several factors are conceivable. The factors include an influence in exhausting a plasma gas from a vacuum treatment chamber while etching is being executed regardless of the lower layer resist film and the film to be etched, and an influence of a stress caused by a reaction product that unevenly adheres to both sides of the lower layer resist film side walls while the film to be etched is being etched. The above influences cause the pattern collapse when using plasma in which the reaction product is excessively generated, or when the material strength of the lower layer resist film is dynamically more brittle.

In etching an insulating film such as a silicon dioxide film using the multilayer resist mask, the above-mentioned pattern collapse is generated. In general, in etching the insulating film such as the silicon dioxide film, with the use of plasma mainly containing fluorocarbon high in deposition property, the insulating film is etched by injection of ions high in energy. When the insulating film is thus etched, the unevenness of the deposition of the reaction product on both sides of the pattern side walls becomes pronounced due to the influences of the high deposition property and the high energy. For that reason, when the above-mentioned plasma for etching the insulating film has a high selectivity with respect to the lower layer resist film, or in a mask pattern high in aspect ratio, the line-wiggling or the striation pronouncedly occurs. As a method of preventing or suppressing the occurrence of the line-wiggling or the striation, it is effective to change the material quality of the lower layer resist film in order to increase the strength of the lower layer resist film. Also, in the case of etching the insulating film with the use of the multilayer resist mask, there are a method of keeping the deposition property of the plasma of the insulating film etching low, a method of reducing the energy at the time of injecting ions, and a method of reducing the exhaust rate in order to reduce the influence of the exhaust gas. However, the effective solution for preventing or suppressing the occurrence of the line-wiggling or the striation in a dry etching using the multilayer resist mask, which results in a worked configuration that is different from a desired pattern configuration after the pattern working has been performed, has not been found at present.

The present invention has been made in view of the above circumstances, and therefore an object of the present invention is to provide a dry etching method that prevents or suppresses the occurrence of line-wiggling or striation in a dry etching using a multilayer resist mask.

According to the present invention, there is provided a plasma etching method for etching a film to be etched by plasma with the use of a multilayer resist mask, in which the multilayer resist mask includes an upper layer resist, an inorganic intermediate film, and a lower layer resist, the method comprising: a side wall protective film forming process of forming a side wall protective film on a side wall of the lower layer resist.

According to the present invention, in the dry etching of a substrate to be treated with the use of the multilayer resist mask, the collapse of the working pattern can be prevented or suppressed. For that reason, the occurrence of the line-wiggling or the striation can be prevented or suppressed.

### BRIEF DESCRIPTION OF THE DRAWINGS

FIG. 1 is a general cross-sectional view illustrating the configuration of a UHF plasma etching device according to an embodiment of the present invention;

FIGS. 2A to 2C are diagrams illustrating a process flow for forming a multilayer resist mask according to the embodiment of the present invention;

FIGS. 3A to 3C are diagrams illustrating a silicon dioxide film etching result when the side wall protective film forming process according to the embodiment of the present invention is applied; and

FIGS. 4A to 4C are diagrams illustrating a silicon dioxide film etching result in a conventional multilayer resist mask.

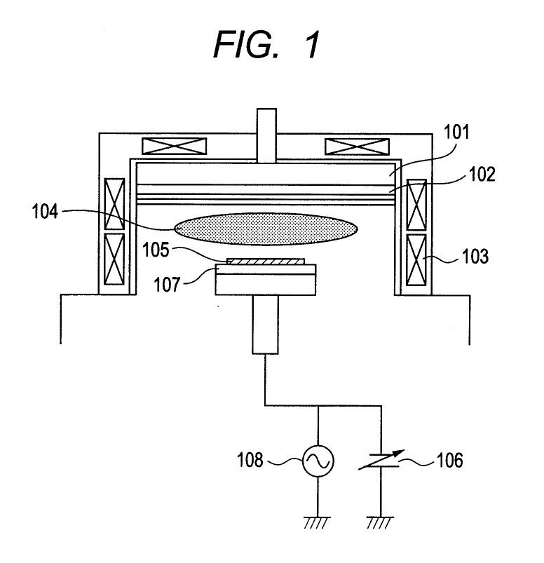

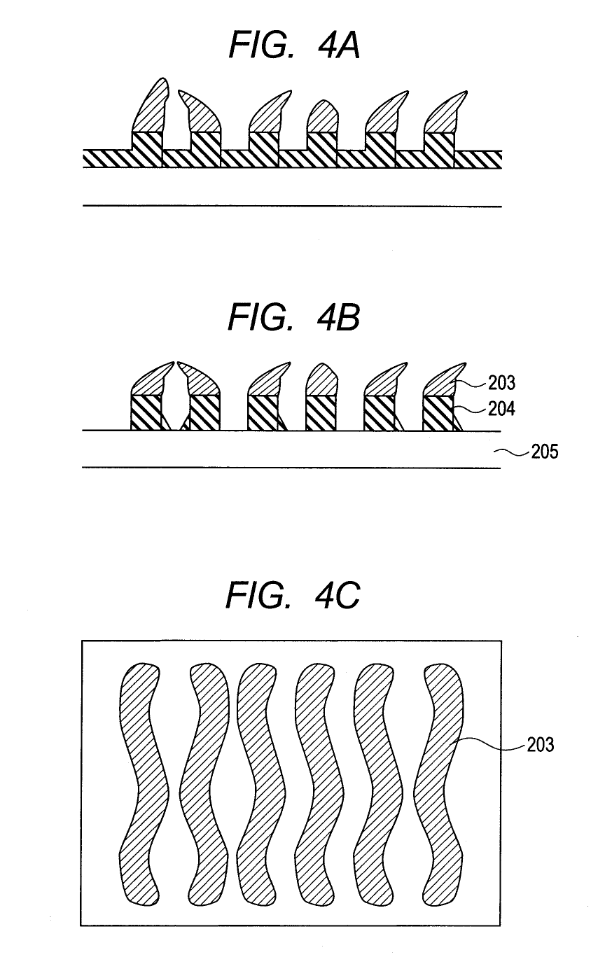

Hereinafter, the respective examples of the present invention will be described with reference to FIGS. 1 to 3C.

FIG. 1 is a diagram illustrating the configuration of an ultra high frequency (UHF) plasma etching device according to an embodiment of the present invention. A UHF wave input from a UHF power supply (not shown) which is a plasma source sequentially passes through an antenna 101 and a UHF transmission plate 102, and reaches the interior of a vacuum treatment chamber. Thereafter, electron cyclotron resonance (ECR) is induced with a process gas due to an interaction with a magnetic field developed by a solenoid coil 103 which is disposed around the vacuum treatment chamber. Then, a high-density plasma 104 is generated within the vacuum treatment chamber.

After the plasma 104 has been generated within the vacuum treatment chamber, a wafer 105 which is a substrate to be treated is electrostatically adsorbed onto a lower electrode 107 by the aid of a DC voltage that is applied from an electrostatic adsorption power supply 106. Also, a high frequency bias power is applied to the lower electrode 107 due to a high frequency power supply 108, and an accelerating voltage is applied to ions in the plasma 104 toward a wafer 105 direction (downward), to thereby draw the ions and start the processing.

Also, a fluorine inert fluid circulates within the lower electrode 107 (not shown), and the lower electrode 107 is connected to a temperature control device (not shown) having a temperature adjusting mechanism (not shown) which is located out of the plasma etching device. Therefore, the temperature of the surface of the wafer 105 that is put on the lower electrode 107 can be controlled by the temperature control device through the circulating fluorine inert fluid.

Also, during plasma etching, a pressure within the vacuum treatment chamber can be adjusted to a given pressure by the aid of an exhaust unit that is made up of a dry pump, a turbo-molecular pump, and a variable valve disposed between the turbo-molecular pump and the vacuum treatment chamber.

### FIRST EXAMPLE

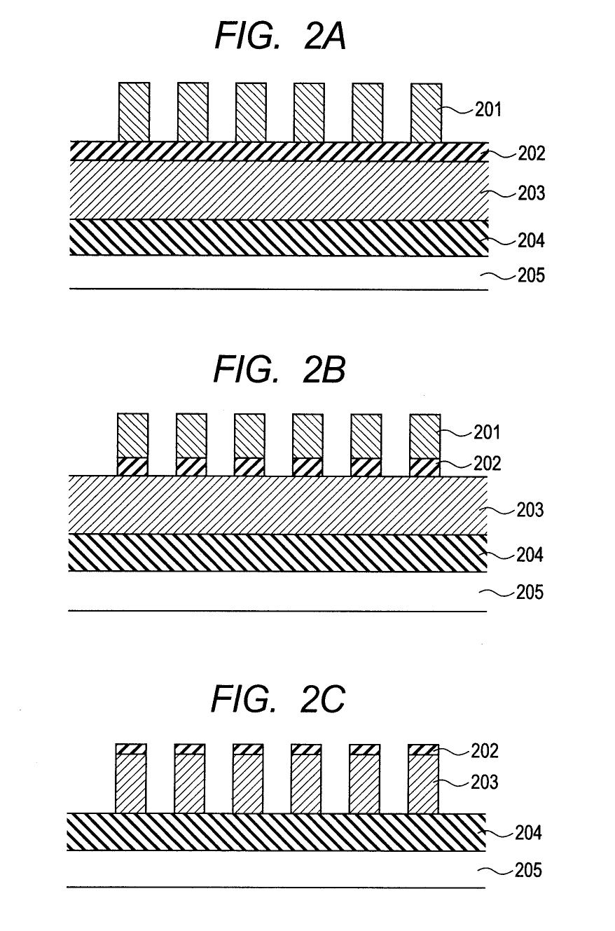

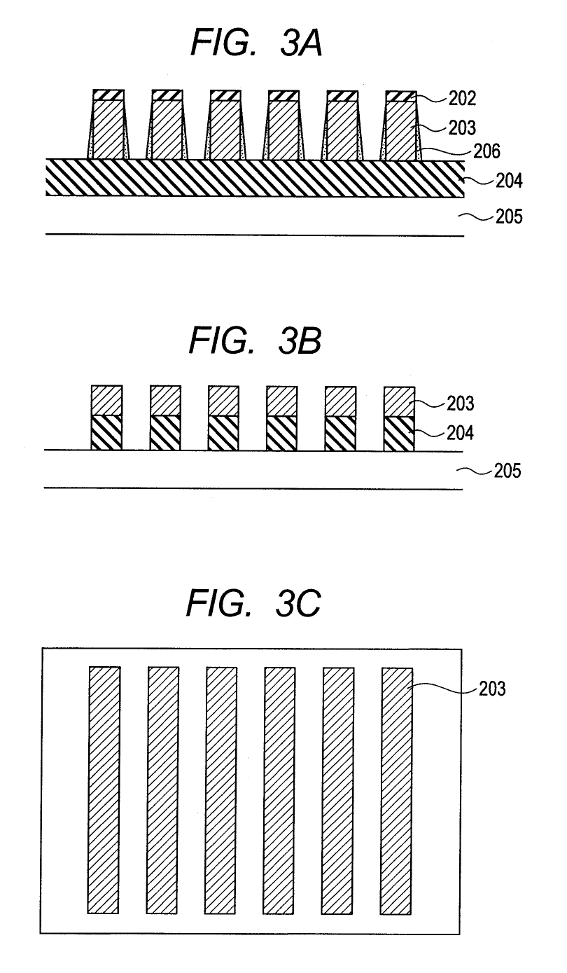

FIGS. 2A to 2C and 3A to 3C illustrate an example in which a silicon dioxide film 204 is etched by plasma with a multilayer resist made up of an upper layer resist film 201, an inorganic intermediate film 202, and a lower layer resist film 203 which is an organic film as a mask with the use of the above-described UHF plasma etching device shown in FIG. 1.

FIG. 2A illustrates the structure of films formed on a wafer before being etched. The multilayer resist is formed of three layers consisting of the upper layer resist film 201 that has been exposed and patterned through the lithography technique, the inorganic intermediate film 202, and the lower layer resist film 203 that is higher in plasma resistance property than the upper layer resist film 201, beginning at the top. The silicon dioxide film 204 that is a film to be etched is formed on a silicon substrate 205 and below the multilayer resist mask. Subsequently, a method of etching the silicon dioxide film 204 with the use of the multiplayer resist mask shown in FIG. 2A will be described. First, the inorganic intermediate film 202 is etched by using a mixed gas containing SF₆ and CHF₃ with the upper layer resist film 201 as a mask (FIG. 2B). Then, the lower layer resist film 203 is etched by using a mixed gas containing O₂, HBr, and N₂ with the upper layer resist film 201 and the inorganic intermediate film 202 as a mask (FIG. 2C).

Then, as shown in Table 1, plasma processing using a mixed gas consisting of SiCl₄, CHF₃, and N₂ is conducted.

TABLE 1
SIDE WALL PROTECTIVE FILM FORMING CONDITIONS

| | | | | | HIGH | | |
|---|---|---|---|---|---|---|---|
| GAS FLOW | | | | | FREQUENCY | | |
| RATE | | | PROCESS | UHF | BIAS | ELECTRODE | PROCESS |
| (ml/min) | | | PRESSURE | POWER | POWER | TEMPERATURE | TIME |
| CHF₃ | N₂ | SiCl₄ | (Pa) | (W) | (W) | (° C.) | (s) |
| 100 | 50 | 5 | 0.6 | 800 | 100 | 30 | 20 |

Through the plasma processing, a side wall protective film 206 is formed on each side walls of the lower layer resist film 203 as shown in FIG. 3A. Then, the silicon dioxide film 204 is etched by using a mixed gas containing a fluorocarbon system with the lower layer resist film 203 formed with the side wall protective films 206 shown in FIG. 3A as a mask. As a result, an etching configuration excellent in anisotropy which is prevented from the line-wiggling and the striation can be obtained as shown in FIGS. 3B and 3C. FIG. 3C is a top view of the etching configuration of FIG. 3B. The reasons that the etching configuration excellent in anisotropy which is prevented from the line-wiggling and the striation can be obtained as shown in FIGS. 3B and 3C are conceivable as follows. After the lower layer resist film 203 has been etched (FIG. 2C), the plasma processing is conducted by using the mixed gas consisting of CHF₃, N₂, and SiCl₄ as shown in Table 1, to thereby generate reaction products of SiC and SiN from an SiCl₄ gas in addition to carbon reaction products such as CₓN_{y} and CₓF_{y} which are derived from N elements of an N₂ gas and C elements of the CHF₃ gas. Those several kinds of reaction products are deposited on the side walls of the lower layer resist film 203. A film that has been deposited on each of the side walls of the lower layer resist film 203 acts as a film that protects the side wall, to thereby increase the strength of the lower layer resist film 203. The resistance property to a stress due to the reaction products increases, thereby enabling the pattern collapse to be suppressed.

In this example, the side wall protective film forming conditions are that the ratio of added SiCl₄ gas to the entire gas flow rate (a sum of a CHF₃ gas flow rate, an N₂ gas flow rate, and an SiCl₄ gas flow rate) is set to about 3%, the process pressure is set to 0.6 Pa, and the high frequency bias power to be applied to the wafer is set to 100 W, as shown in Table 1. Incidentally, the above ratio of about 3% is in a range of from 2.7% to 3.3%. Also, the plasma process time is set to about 20 seconds.

For the purpose of preventing the pattern collapse, it is desirable that the ratio of the added SiCl₄ gas is 1 to 5% of the entire gas flow rate. The reason is as follows. In forming the side wall protective films on the lower layer resist film 203 by the aid of the mixed gas consisting of SiCl₄, CHF₃, and N₂, the effect of the side wall protective film formation is different between a pattern dense portion in which intervals between the respective etching patterns are densely arranged, and a pattern nondense portion in which the intervals of the respective etching patterns are separately arranged. When the ratio is 1% or less, the effect of the side wall protective film formation is not found, and when the ratio is 5% or more, the effect of the side wall protective film formation on the pattern nondense portion is higher than that on the pattern dense portion. Therefore, the density difference of the etching configuration between the pattern nondense portion and the pattern dense portion becomes pronounced. Also, it is desirable that the process pressure in conducting the etching processing is 0.1 Pa to 0.8 Pa. This is because when the process pressure is 0.1 Pa or less, the effect of the side wall protective film formation is low, and when the process pressure is 0.8 Pa or more, the above-mentioned pattern density difference of the etching configuration becomes pronounced. Further, it is desirable that the process time is in a range of from 10 seconds to 60 seconds. This is because when the process time is 10 seconds or less, the pattern collapse cannot be suppressed due to the insufficient side wall protective film formation, and when the process time is 60 seconds or more, the pattern density configuration of the etching configuration becomes pronounced. Furthermore, it is desirable that the high frequency bias power to be supplied to the wafer is 0 to 200 W. This is because when the high frequency bias power is 200 W or more, the remaining portion of the mask is decreased, or the scraping of the silicon substrate 205 is increased.

The high frequency power supply 108 is a high frequency power supply of sine waves having 400 kHz. Alternatively, this example may employ a time modulation bias (hereinafter referred to as “TM bias”) that intermittently supplies a high frequency bias power with 400 kHz. In the case where the TM bias is used, the high frequency power is set to 200 W as shown in Table 2. Also, when an on-time of the TM bias is t1, and an off-time of the TM bias is t2, it is assumed that a duty ratio which is t1/(t1+t2) is 50%.

TABLE 2
SIDE WALL PROTECTIVE FILM FORMING CONDITIONS

| | | | | | HIGH | | |
|---|---|---|---|---|---|---|---|
| | | | | | FREQUENCY | | |
| | | | | | BIAS | | |
| GAS FLOW RATE | | | PROCESS | UHF | POWER | ELECTRODE | PROCESS |
| (ml/min) | | | PRESSURE | POWER | (TM BIAS) | TEMPERATURE | TIME |
| CHF₃ | N₂ | SiCl₄ | (Pa) | (W) | (W) | (° C.) | (s) |
| 100 | 50 | 5 | 0.6 | 800 | 200 | 30 | 20 |

In the case where the TM bias is used, the reaction product is liable to be deposed on the mask or the silicon dioxide film 204 when the TM bias is off. For that reason, the remaining portion of the mask can be improved, and the effect of suppressing the scraping of the silicon dioxide film 204 can be obtained.

Further, this example is implemented at the electrode temperature of 30° C., but the effect of the side wall protective film formation is further enhanced by decreasing the electrode temperature. However, the dimensions of the etching configuration after etching has been conducted are increased by increasing the deposition property of the reaction product due to a reduction in the electrode temperature. For that reason, there is a need to optimize the gas flow rate of CHF₃, N₂, and SiCl₄, such that the CHF₃ gas flow rate is decreased.

### SECOND EXAMPLE

A second example is an example in which the side wall protective film is formed on the side walls of the lower layer resist film 203 with the use of a mixed gas consisting of SiCl₄ and HBr after the lower layer resist film 203 has been etched.

The process till the pattern formation of the lower layer resist film 203 is identical with that in the first example, and therefore will be omitted from description.

After the pattern of the lower layer resist film 203 has been formed (FIG. 2C), the silicon dioxide film 204 is etched with the lower layer resist film 203 formed with the side wall protective film under the conditions shown in Table 3 as a mask. As a result, the etching configuration excellent in anisotropy which is prevented from the line-wiggling and the striation can be obtained without collapse of the pattern. It is conceivable that the effect is obtained for the following reasons. Because SiₓBr_{y} which is a reaction product is deposited on the side walls of the lower layer resist film 203, the strength of the lower layer resist film 203 is increased, and the resistance property to the stress due to the reaction production is increased, thereby enabling the pattern collapse to be suppressed. Because SiₓBr_{y} which is a reaction product containing Si is higher in the effect of the side wall protective film formation than CₓN_{y} and CₓF_{y} which are the carbon reaction products, it is conceivable that the resistance property of the lower layer resist film 203 to the stress due to the reaction product can be increased by only SiₓBr_{y}.

TABLE 3
SIDE WALL PROTECTIVE FILM FORMING CONDITIONS

| | | | | HIGH | | |
|---|---|---|---|---|---|---|
| GAS FLOW | | | | FREQUENCY | | |
| RATE | | PROCESS | UHF | BIAS | ELECTRODE | PROCESS |
| (ml/min) | | PRESSURE | POWER | POWER | TEMPERATURE | TIME |
| HBr | SiCl₄ | (Pa) | (W) | (W) | (° C.) | (s) |
| 90 | 10 | 0.6 | 800 | 100 | 30 | 20 |

It is desirable that the ratio of added SiCl₄ is 1 to 12% of the entire gas flow rate. The reason is as follows. When the ratio is 0.1% or less, the effect of the side wall protective film formation is not found. When the ratio is 12% or more, the effect of the side wall protective film formation on the pattern nondense portion is higher than that on the pattern dense portion, and therefore the density difference of the etching configuration between the pattern nondense portion and the pattern dense portion becomes pronounced. It is desirable that the process time is in a range of from 10 seconds to 60 seconds. This is because when the process time is 10 seconds or less, the pattern collapse cannot be suppressed, and when the process time is 60 seconds or more, the pattern density difference becomes pronounced. Because the fluorocarbon gas containing carbon is not contained in a gas that makes up plasma, it is difficult to generate CₓN_{y} and CₓF_{y} which are the carbon reaction products. Therefore, the etching configuration small in the pattern density difference can be obtained as compared with the first example. Also, since the carbon reaction products that can constitute a foreign matter source are small in the amount, a foreign matter can be suppressed, and the frequency of plasma cleaning for removal of the foreign matter can be reduced.

### THIRD EXAMPLE

A third example is an example in which the side wall protective film is formed on the side walls of the lower layer resist film 203 with the use of a mixed gas consisting of SiCl₄ and CH₂F₂ after the lower layer resist film 203 has been etched. The process till the pattern formation of the lower layer resist film 203 is identical with that in the first example, and therefore will be omitted from description.

After the pattern of the lower layer resist film 203 has been formed (FIG. 2C), the silicon dioxide film 204 is etched with the lower layer resist film 203 formed with the side wall protective film under the conditions shown in Table 4 as a mask. As a result, the etching configuration excellent in anisotropy which is prevented from the line-wiggling and the striation can be obtained without collapse of the pattern. It is conceivable that the effect is obtained for the following reasons. Because CₓF_{y} and SiC which are the reaction products are deposited on the side walls of the lower layer resist film 203, the strength of the lower layer resist film 203 is increased, and the resistance property to the stress due to the reaction production is increased, thereby enabling the pattern collapse to be suppressed.

TABLE 4
SIDE WALL PROTECTIVE FILM FORMING CONDITIONS

| | | | | HIGH | | |
|---|---|---|---|---|---|---|
| GAS FLOW | | | | FREQUENCY | | |
| RATE | | PROCESS | UHF | BIAS | ELECTRODE | PROCESS |
| (ml/min) | | PRESSURE | POWER | POWER | TEMPERATURE | TIME |
| CH₂F₂ | SiCl₄ | (Pa) | (W) | (W) | (° C.) | (s) |
| 95 | 5 | 0.6 | 800 | 100 | 30 | 20 |

It is desirable that the ratio of added SiCl₄ is 1 to 10% of the entire gas flow rate. This is because when the ratio is 1% or less, the effect of the side wall protective film formation is not found, and when the ratio is 10% or more, the effect of the side wall protective film formation on the pattern nondense portion is higher than that on the pattern dense portion, and therefore the density difference of the etching configuration between the pattern nondense portion and the pattern dense portion becomes pronounced. It is desirable that the process time is in a range of from 10 seconds to 60 seconds. This is because when the process time is 10 seconds or less, the pattern collapse cannot be suppressed, and when the process time is 60 seconds or more, the pattern density configuration difference becomes pronounced. Because a CH₂F₂ gas which is fluorocarbon is liable to generate the carbon reaction product CₓF_{y} as compared with a CHF₃ gas used in the first example, the same effect as that in the first example can be obtained even if no N₂ gas is added. Accordingly, this example can improve the mass production stability because the pattern collapse can be suppressed with the smaller amount of mixed gas than that in the first example.

### FOURTH EXAMPLE

A fourth example is an example in which etching of the silicon dioxide film 204 includes three processes consisting of a process of etching the silicon dioxide film 204 with the use of a mixed gas containing a fluorocarbon system, a process of forming the side wall protective films 206 on the side walls of the lower layer resist film 203 with the use of a mixed gas consisting of HBr and N₂, and a process of etching the silicon dioxide film 204 with the use of a mixed gas containing the fluorocarbon system. The process till the pattern formation of the lower layer resist film 203 is identical with that in the first example, and therefore will be omitted from description. After the pattern of the lower layer resist film 203 has been formed (FIG. 2C), the silicon dioxide film 204 is etched to a given depth (a depth that does not reach the silicon substrate 205) with the use of a mixed gas consisting of SF₆ and CHF₃, with the lower layer resist film 203 as a mask. Then, the side wall protective films are formed on the side walls of the lower layer resist film 203 with the use of the mixed gas consisting of HBr and N₂ as shown in Table 5. With the lower layer resist film 203 formed with the side wall protective film under the conditions shown in Table 5, the silicon dioxide film 204 with the remaining depth is etched. As a result, the etching configuration excellent in anisotropy which is prevented from the line-wiggling and the striation can be obtained without collapse of the pattern.

TABLE 5
SIDE WALL PROTECTIVE FILM FORMING CONDITIONS

| | | | | HIGH | | |
|---|---|---|---|---|---|---|
| GAS FLOW | | | | FREQUENCY | | |
| RA TE | | PROCESS | UHF | BIAS | ELECTRODE | PROCESS |
| (ml/min) | | PRESSURE | POWER | POWER | TEMPERATURE | TIME |
| HBr | N₂ | (Pa) | (W) | (W) | (° C.) | (s) |
| 100 | 10 | 1.6 | 800 | 0 | 30 | 20 |

It is conceivable that this is caused for the following reason. The silicon dioxide film 204 is etched partway to etch and remove the inorganic intermediate film 202 that is a mask. At a time point when the lower layer resist film 203 is exposed, the side walls and the upper portions of the lower layer resist film 203 are covered with the side wall protective film. As a result, the pattern collapse can be reduced.

In this embodiment, because no high frequency bias power is supplied, the power consumption can be reduced as compared with the other examples. This enables the running costs to be reduced.

Except for the fourth example among the first to fourth examples, the side wall protection effect in which the reaction products such as SiN and SiC are deposited on the side walls of the lower layer resist film 203 can be enhanced by addition of the SiCl₄ gas. Also, the line-wiggling and the striation during etching of the silicon dioxide film can be suppressed. In the present invention, an example in which the silicon dioxide film is etched has been described. However, the present invention is not limited to this configuration. The present invention can be widely applied to a case in which the other insulating films such as a silicon nitride film and a polysilicon film for forming a gate electrode are etched by plasma with the multilayer resist as a pattern mask.

As described above, in the present invention, the plasma etching device using the interaction with a magnetic field using a UHF wave as the plasma source is exemplified. However, the present invention is not limited to this configuration. For example, the present invention can be applied to a plasma etching device using a microwave ECR, a helicon wave, or an inductive coupling or capacitive coupling plasma source. Also, the present invention targets the wafer of φ300 mm, but can be applied to wafers of φ200 mm and φ450 mm.

What is claimed is:

1. A plasma etching method of etching a film to be etched by plasma with the use of a multilayer resist mask, in which the multilayer resist mask includes an upper layer resist, an inorganic intermediate film, and a lower layer resist, the method comprising:
a side wall protective film forming step of forming a side wall protective film on a side wall of the lower layer resist.

2. The plasma etching method according to claim 1, wherein the side wall protective film forming step is conducted after the lower layer resist etching step.

3. The plasma etching method according to claim 1, wherein the side wall protective film forming step is conducted by plasma of a mixed gas containing CHF₃, N₂, and SiCl₄.

4. The plasma etching method according to claim 1, wherein the side wall protective film forming step is conducted after the lower layer resist etching step, and also conducted by plasma of a mixed gas containing CHF₃, N₂, and SiCl₄.
